(19) United States
(12) Patent Application Publication
(10) Pub. No.: US 2018/0170689 A1
(43) Pub. Date: Jun. 21, 2018

(54) SUBSTRATE DELIVERY DEVICE AND DELIVERY METHOD THEREOF

(71) Applicants: Boe Technology Group Co., Ltd., Beijing (CN); Beijing Boe Display Technology Co., Ltd., Beijing (CN)

(72) Inventors: Le Qi, Beijing (CN); Fuyuan Sun, Beijing (CN); Long Li, Beijing (CN); Jin Zhang, Beijing (CN); Yunlong Han, Beijing (CN); Dongsheng Xu, Beijing (CN); Bin Cao, Beijing (CN)

(21) Appl. No.: 15/513,968

(22) PCT Filed: May 30, 2016
(86) PCT No.: PCT/CN2016/083884

§ 371 Date: Mar. 23, 2017

(30) Foreign Application Priority Data
Mar. 21, 2016 (CN) 201610162770.5

(51) Int. Cl. B65G 47/91; B65G 49/06; H01L 21/683; H01L 21/677; G02F 1/13

(52) U.S. Cl. CPC B65G 47/91; B65G 49/067; H01L 21/6838; B65G 2249/04; G02F 1/1303; H01L 21/6773; H01L 21/67718

(57) ABSTRACT

A substrate delivery device and a delivery method thereof are described for improving the substrate delivery efficiency, reducing abrasion in substrate delivery, and improving manufacturing efficiency of a display panel. The substrate delivery device comprises a reciprocating aligning mechanism and a screen pickup mechanism. The reciprocating aligning mechanism has a bearing platform carrying the substrate, and a first driving mechanism driving the bearing platform to move so as to bring the carried substrate to a preset position. The screen pickup mechanism has a pickup arm picking up a substrate on the reciprocating aligning mechanism, and a second driving mechanism driving the pickup arm to move. The pickup arm is located in a direction perpendicular to the substrate on the reciprocating aligning mechanism. When the reciprocating aligning mechanism moves to the preset position, the second driving mechanism drives the pickup arm to pick up the substrate on the reciprocating aligning mechanism.

### FIELD

This disclosure relates to the field of display technology, particularly to a substrate delivery device and a delivery method thereof.

### BACKGROUND

At present, the conveyer belt device is widely used for conveying glass in the LCD manufacture industry. The upper part of the conventional conveyer belt device consists of rollers so as to drive the glass to move forward. In the lower part of the conveyer belt device, a motor is connected with the rollers through gears or magnet rings. The motor rotates so as to drive the rollers to move. After the glass reaches the preset position, a mechanical hand takes the glass away.

However, when the conveyer belt device in the prior art delivers glass, it can only deliver the glass one by one, and the delivery is driven mainly by means of the friction between the rollers and the glass. Hence, the delivery speed is low, which may influence the production efficiency. Moreover, because the rollers are in contact with the glass, the relative sliding may also result in scratch to the glass easily, which may influence the quality of the glass.

### SUMMARY

According to one aspect of this disclosure, a substrate delivery device is provided, comprising a reciprocating aligning mechanism and a screen pickup mechanism. The reciprocating aligning mechanism comprises: a bearing platform for carrying the substrate, and a first driving mechanism for driving the bearing platform to move so as to bring the carried substrate to a preset position. The screen pickup mechanism comprises: a pickup arm for picking up a substrate on the reciprocating aligning mechanism, and a second driving mechanism for driving the pickup arm to move. The pickup arm is located in a direction perpendicular to the substrate on the reciprocating aligning mechanism, and when the reciprocating aligning mechanism moves to the preset position, the second driving mechanism is used for driving the pickup arm to pick up the substrate on the reciprocating aligning mechanism.

When the substrate delivery device provided by this disclosure delivers the substrate, the substrate to be delivered is placed on the bearing platform of the reciprocating aligning mechanism. The first driving mechanism in the reciprocating aligning mechanism drives the bearing platform to move so as to bring the substrate carried thereon to the preset position. When the bearing platform drives the substrate carried thereon to move, the substrate and the bearing platform are fixed relative to each other. The second driving mechanism in the screen pickup mechanism drives the pickup arm to pick up the substrate on the reciprocating aligning mechanism. The reciprocating aligning mechanism moves to the initial position and delivers a new substrate again.

When the substrate delivery device provided by this disclosure delivers the substrate, there is no relative friction between the substrate and the mechanism that drives it to move. In this way, the occurrence of the substrate abrasion phenomenon can be reduced. In addition, the reciprocating aligning mechanism can perform alignment at the same time of delivering the substrate. When the substrate thereon is taken away, it will return and continue to deliver the substrate, so that the delivery efficiency is relatively high. Hence, the substrate delivery device provided by this disclosure can improve the substrate delivery efficiency, reduce the abrasion in substrate delivery, and improve the manufacturing efficiency of the display panel.

Optionally, the substrate delivery device further comprises: at least one screen release arm. The screen pickup mechanism transfers the picked-up substrate onto the at least one screen release arm. Each of the at least one screen release arm comprises: a delivery platform for carrying the substrate transferred by the screen pickup mechanism, and a third driving mechanism for driving the delivery platform to move. The screen pickup mechanism can return back to pick up a new substrate after placing the substrate thereon onto the screen release arm, thus the delivery efficiency of the substrate delivery device can be further improved.

Optionally, the number of the at least one screen release arm is two, and the two screen release arms are in axial symmetry relative to a moving direction of any screen release arm.

Optionally, the first driving mechanism comprises: a first driving unit for driving the bearing platform to move along a first direction, and a second driving unit for driving the bearing platform to move along a second direction. The second direction is parallel to arrangement direction of the two screen release arms, and the first direction is perpendicular to the second direction.

Optionally, the first driving unit comprises: a first lead screw and a first driving motor for driving the first lead screw to rotate, the bearing platform being in sliding connection with the first lead screw; and/or, the second driving unit comprises: a second lead screw and a second driving motor for driving the second lead screw to rotate, the bearing platform being in sliding connection with the second lead screw. The lead screw can convert the rotary motion of the driving motor into linear motion.

Optionally, the substrate delivery device further comprises: a guide rail located above the reciprocating aligning mechanism. An extending direction of the guide rail is parallel to the second direction; and the screen pickup mechanism can be connected with the reciprocating aligning mechanism through the guide rail.

Optionally, the second driving mechanism comprises: a third driving unit for driving the pickup arm to move along a third direction, and a fourth driving unit for driving the pickup arm to move along the second direction. The third direction is perpendicular to both the first direction and the second direction.

Optionally, the third driving unit is arranged within a mounting rack, and the third driving unit comprises: a third lead screw and a third driving motor for driving the third lead screw to rotate, the pickup arm being in sliding connection with the third lead screw; and/or, the fourth driving unit comprises: a fourth lead screw and a fourth driving motor for driving the fourth lead screw to rotate, the mounting rack being in sliding connection with the fourth lead screw.

Optionally, the pickup arm is provided with a vacuum chuck for adsorbing the substrate.

Optionally, the delivery platform is provided with a plurality of vacuum suction holes for adsorbing the substrate transferred by the screen pickup mechanism.

Optionally, the third driving mechanism comprises: a fifth lead screw and a fifth driving motor for driving the fifth lead screw to rotate, the delivery platform being in sliding connection with the fifth lead screw.

Optionally, the substrate delivery device further comprises:
a storage catridge arranged at one end of each of the at least one screen release arm away from the reciprocating aligning mechanism, for storing the substrate delivered by each screen release arm, wherein the storage catridge comprises at least two layers of storage cabinet, each layer of storage cabinet being used for accommodating one substrate;

a fourth driving mechanism corresponding to the storage catridge, for driving the corresponding storage catridge to move along a third direction; wherein the third direction is perpendicular to both the first direction and the second direction.

According to the other aspect of this disclosure, a delivery method applied to the substrate delivery device as stated by any of the above is further provided, comprising:

step one: placing a substrate to be delivered on the bearing platform of the reciprocating aligning mechanism;

step two: the first driving mechanism in the reciprocating aligning mechanism driving the bearing platform to move so as to bring the carried substrate to a preset position;

step three: the second driving mechanism in the screen pickup mechanism driving the pickup arm in the screen pickup mechanism to pick up the substrate on the reciprocating aligning mechanism.

Optionally, when the substrate delivery device comprises at least one screen release arm, the delivery method further comprises:

step four: the first driving mechanism in the reciprocating aligning mechanism driving the bearing platform to move to an initial position, and repeating the step one, the step two and the step three; meanwhile, repeating the step four after the second driving mechanism in the screen pickup mechanism drives the pickup arm in the screen pickup mechanism to transfer the picked-up substrate to a screen release arm.

Optionally, when the substrate delivery device comprises a storage catridge, the delivery method further comprises:

step five: the screen release arm being used for delivering the substrate thereon into a storage cabinet of the storage catridge;

step six: controlling the storage catridge to move one storage cabinet along the third direction so as to receive a next substrate, repeating the step five and the step six until the storage catridge is filled fully with substrates. Then, the mechanical hand in the next manufacturing process picks up the storage catridge that is filled fully with substrates.

### BRIEF DESCRIPTION OF THE DRAWINGS

The drawings explained here are used for providing further understanding to this disclosure, and constitute a part of this disclosure. The example embodiments of this disclosure and the explanations thereof are used for explaining this disclosure rather than constituting limitations to this disclosure. In the drawings:

FIG. 1 is a schematic structural view of a substrate delivery device according to embodiments of this disclosure;

FIG. 2 is a schematic structural view of a reciprocating aligning mechanism according to embodiments of this disclosure;

FIG. 3 is a schematic sectional view of a screen pickup mechanism according to embodiments of this disclosure;

FIG. 4 is a schematic sectional view of a screen release arm according to embodiments of this disclosure.

### DETAILED DESCRIPTION

In the drawings, the reference numbers involved are listed as:

| | |
|---|---|
| 1-substrate | 2-reciprocating aligning mechanism |
| 20-first driving mechanism | 21-bearing platform |
| 22-first driving unit | 23-second driving unit |
| 221-first lead screw | 222-first driving motor |
| 231-second lead screw | 232-second driving motor |
| 3-guide rail | 4-screen pickup mechanism |
| 40-second driving mechanism | 41-mounting rack |
| 42-pickup arm | 421-vacuum chuck |
| 43-third driving unit | 44-fourth driving unit |
| 5-screen release arm | 51-delivery platform |
| 52-third driving mechanism | 53-fifth lead screw |
| 54-fifth driving motor | 6-storage catridge |
| 7-fourth driving mechanism | X-first direction |
| Y-second direction | Z-third direction |

Next, the technical solutions in embodiments of this disclosure will be described clearly and completely with reference to the drawings. Apparently, the embodiments described are only exemplary rather than restrictive.

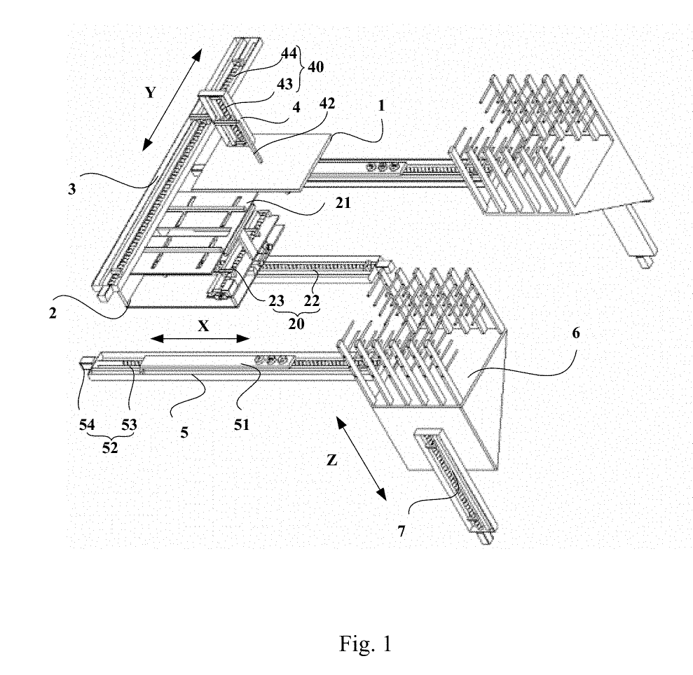

FIG. 1 is a schematic structural view of a substrate delivery device according to embodiments of this disclosure. The substrate delivery device comprises: a reciprocating aligning mechanism 2 and a screen pickup mechanism 4. The reciprocating aligning mechanism 2 comprises: a bearing platform 21 for carrying a substrate 1 to be delivered, and a first driving mechanism 20 for driving the bearing platform 21 to move so as to bring the carried substrate 1 to a preset position. The screen pickup mechanism 4 comprises: a pickup arm 42 for picking up the substrate 1 on the reciprocating aligning mechanism 2, and a second driving mechanism 40 for driving the pickup arm 42 to move. The pickup arm is located in a direction perpendicular to the substrate on the reciprocating aligning mechanism 2. When the first driving mechanism of the reciprocating aligning mechanism moves the carried substrate to the preset position, the second driving mechanism drives the pickup arm 42 to pick up the substrate 1 on the reciprocating aligning mechanism 2.

When the substrate delivery device delivers the substrate 1, the substrate 1 to be delivered is placed on the bearing platform 21 of the reciprocating aligning mechanism 2. The first driving mechanism in the reciprocating aligning mechanism 2 drives the bearing platform 21 to move so as to bring the substrate 1 carried thereon to the preset position. When the bearing platform 21 is driven so as to drive the substrate 1 carried thereon to move, the substrate 1 and the bearing platform 21 are fixed relative to each other. The second driving mechanism 40 in the screen pickup mechanism 4 drives the pickup arm 42 to pick up the substrate 1 on the reciprocating aligning mechanism 2. Then, the reciprocating aligning mechanism 2 moves to the initial position and delivers a new substrate 1 again.

When the substrate delivery device provided by this disclosure delivers the substrate 1, there is no relative friction between the substrate 1 and the mechanism that drives it to move, hence, the occurrence of the abrasion phenomenon of the substrate 1 can be reduced. In addition, the reciprocating aligning mechanism 2 can perform alignment at the same time of delivering the substrate 1, and when the substrate 1 thereon is taken away, it will return and continue to deliver the substrate 1. Hence, the substrate delivery device provided by this disclosure can improve the delivery efficiency of the substrate 1, reduce the abrasion in delivery of the substrate 1, and improve the manufacturing efficiency of the display panel.

In other embodiments, as shown in FIG. 1, the substrate delivery device further comprises: at least one screen release arm 5. The screen pickup mechanism 4 transfers the picked-up substrate 1 onto a screen release arm 5. Each of the at least one screen release arm 5 comprises: a delivery platform 51 for carrying the substrate 1 transferred by the screen pickup mechanism 4, and a third driving mechanism 52 for driving the delivery platform 51 to move. The screen pickup mechanism can return back to pick up a new substrate after placing the substrate thereon onto the screen release arm, thus the delivery efficiency of the substrate delivery device can be further improved.

The specific number of the screen release arm 5 can be set based on actual needs. Generally, the number of the screen release arm 5 is two, and the two screen release arms 5 are in axial symmetry relative to a moving direction of any screen release arm 5. The screen pickup mechanism 4 is located between the two screen release arms 5, so that the substrate 1 can be placed on any screen release arm 5 based on needs.

In other embodiments, the substrate delivery device can further comprise: a storage catridge 6 arranged at one end of each of the at least one screen release arm 5 away from the reciprocating aligning mechanism 2 and a fourth driving mechanism 7 corresponding to the storage catridge. The storage catridge 6 is used for storing the substrate 1 delivered by the corresponding screen release arm 5, and the storage catridge 6 comprises at least two layers of storage cabinet, each layer of storage cabinet being used for accommodating one substrate 1. The fourth driving mechanism 7 is used for driving the corresponding storage catridge 6 to move.

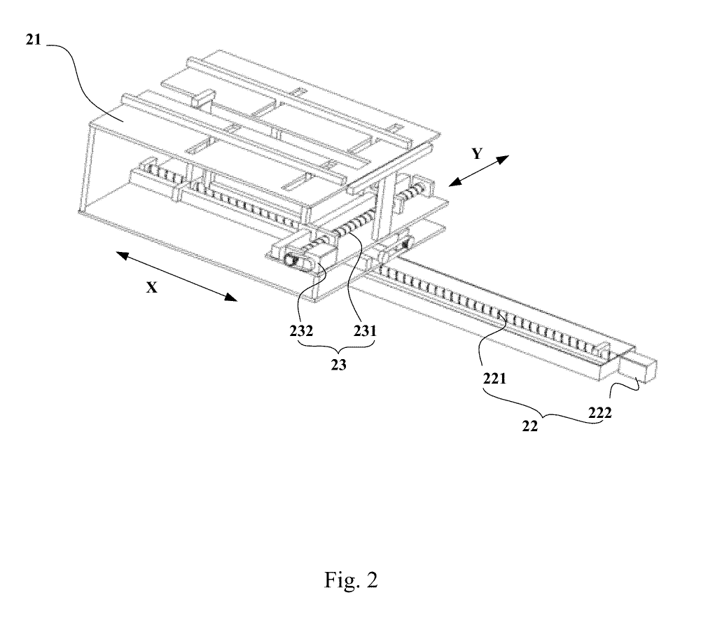

The above reciprocating aligning mechanism 2 can have various specific structures. FIG. 2 is a schematic structural view of a reciprocating aligning mechanism according to embodiments of this disclosure. The first driving mechanism of the reciprocating aligning mechanism comprises: a first driving unit 22 for driving the bearing platform 21 to move along a first direction X, and a second driving unit 23 for driving the bearing platform 21 to move along a second direction Y. The second direction Y is parallel to arrangement direction of the two screen release arms 5, and the first direction X is perpendicular to the second direction Y. The bearing platform 21 can be moved and positioned by controlling the first driving unit 22 and the second driving unit 23, so as to be easy to control.

The first driving unit 22 and the second driving unit 23 can use various structures, as long as the movement of the bearing platform 21 can be achieved. For example, they can be: telescoping cylinders, extendable rods etc.

In embodiments, the first driving unit 22 can comprise a first lead screw 221 and a first driving motor 222 for driving the first lead screw 221 to rotate, wherein the bearing platform 21 is in sliding connection with the first lead screw 221. The second driving unit 23 comprises a second lead screw 231 and a second driving motor 232 for driving the second lead screw 231 to rotate, wherein the bearing platform 21 is in sliding connection with the second lead screw 231. The lead screw can convert the rotary motion of the driving motor into linear motion.

The screen pickup mechanism 4 can be arranged above the reciprocating aligning mechanism 2. The screen pickup mechanism 4 can be arranged above the reciprocating aligning mechanism 2 in various ways. In embodiments, the substrate delivery device can comprise: a guide rail 3 located above the reciprocating aligning mechanism 2. The extending direction of the guide rail 3 can be parallel to the second direction Y. The screen pickup mechanism 4 can be connected with the recriprocating mechanism 2 through the guide rail 3 (e.g., sliding connection), as shown in FIG. 1. Certainly, other connecting manners for connecting the screen pickup mechanism and the reciprocating aligning mechanism are also contemplated.

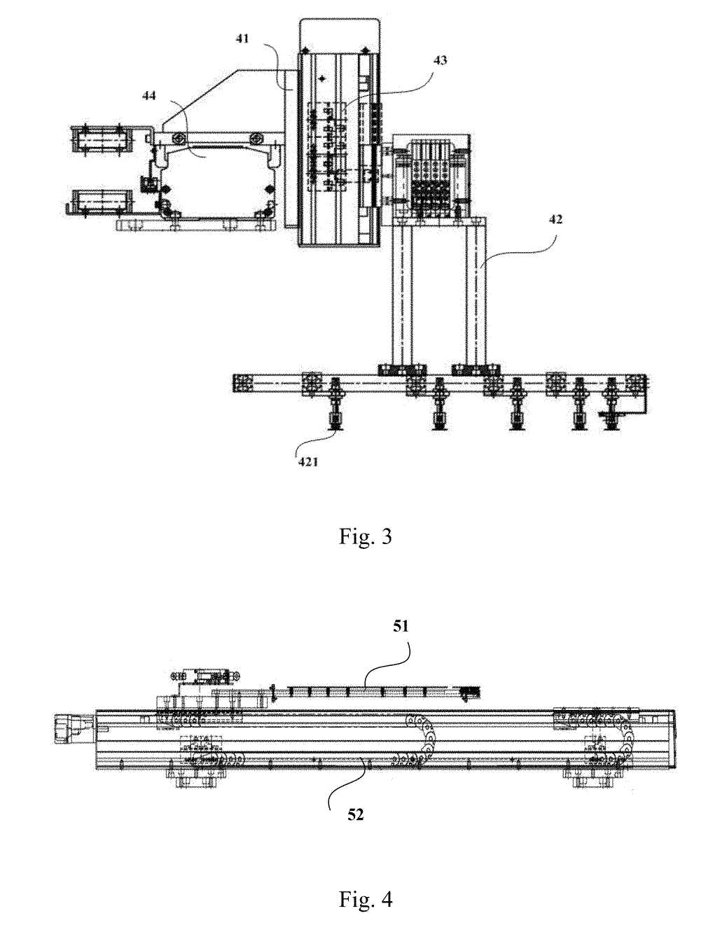

FIG. 3 is a schematic sectional view of a screen pickup mechanism according to embodiments of this disclosure. The second driving mechanism of the screen pickup mechanism comprises: a third driving unit 43 for driving the pickup arm 42 to move along a third direction Z, and a fourth driving unit 44 for driving the pickup arm 42 to move along the second direction Y. The third direction Z is perpendicular to both the first direction X and the second direction Y.

The fourth driving unit 44 can move along the second direction Y, which is convenient for the screen pickup mechanism to pick up and place the substrate 1. In addition, in order to further felicitate the pickup arm 42 to pick up the substrate 1, the pickup arm 42 can be provided with a vacuum chuck 421 for adsorbing the substrate 1. The arrangement of the vacuum chuck 421 can also prevent the substrate 1 from sliding relative to the pickup arm 42, which may result in abrasion of the substrate 1.

The third driving unit 43 can also use various structures. In embodiments, the third driving unit 43 can comprise a third lead screw and a third driving motor for driving the third screw to rotate. The pickup arm 42 is in sliding connection with the third lead screw. When the third driving motor rotates, the third lead screw will also rotate, so that the pickup arm 42 moves along the length direction of the third lead screw, thereby realizing movement of the pickup arm 42 along the third direction Z. The third driving unit can be arranged within a mounting rack 41 and is in sliding connection with the fourth driving unit.

Similarly, the fourth driving unit can be realized using a structure similar as the third driving unit. For example, the fourth driving unit can also comprise a fourth lead screw and a fourth driving motor for driving the lead screw to rotate. The mounting rack can be in sliding connection with the fourth lead screw. When the fourth driving motor rotates, the fourth lead screw will also rotate, so that the pickup arm 42 moves along the length direction of the fourth lead screw, thereby realizing movement of the pickup arm 42 along the second direction Y.

FIG. 4 is a schematic sectional view of a screen release arm according to embodiments of this disclosure. The screen release arm 5 comprises: a delivery platform 51 provided with a plurality of vacuum suction holes for adsorbing the substrate 1 transferred by the screen pickup mechanism.

The third driving mechanism 52 can also use various structure forms. Optionally, the third driving mechanism 52 comprises: a fifth lead screw 53 and a fifth driving motor for driving the fifth lead screw to rotate. The delivery platform 51 is in sliding connection with the fifth lead screw.

As stated above, in other embodiments, the substrate delivery device can further comprise:

a storage catridge 6 arranged at one end of each of the at least one screen release arm 5 away from the reciprocating aligning mechanism 2, for storing the substrate 1 delivered by each screen release arm 5, wherein the storage catridge 6 comprises at least two layers of storage cabinet, each layer of storage cabinet being used for accommodating one substrate 1; and

a fourth driving mechanism 7 corresponding to the storage catridge 6, for driving the corresponding storage catridge 6 to move along the third direction Z.

The mechanical hand in the next manufacturing process can be used for picking up the storage catridge 6 that is filled fully with substrates 1. The third direction is perpendicular to both the first direction and the second direction.

After the screen release arm 5 delivers the substrate 1 thereon into a storage cabinet of the storage catridge 6, the storage catridge 6 moves one layer of storage cabinet along the third direction Z and waits for receiving a next substrate 1, until the storage catridge 6 is filled fully with substrates 1. The mechanical hand in the next manufacturing process picks up the storage catridge 6 that is filled fully with substrates 1. That is to say, the mechanical hand in the next manufacturing process moves the storage catridge 6 away after the storage catridge 6 is filled up. The mechanical hand in the next process can convey a plurality of substrates 1, thus the delivery efficiency of the substrate delivery device and the production efficiency of the display panel can be further improved. Certainly, the mechanical hand can also move the storage catridge 6 away when the storage catridge 6 is not fully filled with substrates 1, which is not restrictive.

To sum up, when the substrate delivery device provided by embodiments of this disclosure delivers the substrate to the mechanical hand in the next process, the substrate to be delivered is placed on the bearing platform of the reciprocating aligning mechanism firstly. The first driving mechanism in the reciprocating aligning mechanism drives the bearing platform to move so as to bring the carried substrate to the preset position. The second driving mechanism in the screen pickup mechanism drives the pickup arm in the screen pickup mechanism to pick up the substrate on the recriprocating aligning mechanism. The first driving mechanism in the reciprocating aligning mechanism drives the bearing platform to move to the initial position so as to deliver a new substrate again. Meanwhile, after the second driving mechanism in the screen pickup mechanism drives the pickup arm in the screen pickup mechanism to transfer the picked-up substrate to a screen release arm, the pickup arm returns back to pickup a new substrate on the reciprocating aligning mechanism. The screen release arm delivers the substrate thereon into a storage cabinet of the storage catridge, and then returns back to pickup a new substrate again. The storage catridge moves a layer of storage cabinet along the third direction so as to receive a next substrate. Optionally, after the storage catridge is filled fully with substrates, the mechanical hand in the next process picks up the storage catridge that is filled fully with substrates. In this way, the mechanical hand in the next process can pick up a plurality of substrates at a time, such that the moving frequency of the mechanical hand in the next process is reduced, so as to improve the production efficiency of the display panel.

This disclosure further provides a delivery method applied to the substrate delivery device as stated by any of the above, comprising:

step one: placing a substrate to be delivered on the bearing platform of the reciprocating aligning mechanism;

step two: the first driving mechanism in the reciprocating aligning mechanism driving the bearing platform to move so as to bring the carried substrate to a preset position;

step three: the second driving mechanism in the screen pickup mechanism driving the pickup arm in the screen pickup mechanism to pick up the substrate on the reciprocating aligning mechanism.

Further, when the substrate delivery device comprises at least one screen release arm, the delivery method further comprises:

step four: the first driving mechanism in the reciprocating aligning mechanism driving the bearing platform to move to an initial position, and repeating the step one, the step two and the step three; meanwhile, repeating the step four after the second driving mechanism in the screen pickup mechanism drives the pickup arm in the screen pickup mechanism to transfer the picked-up substrate to a screen release arm of multiple of screen release arms.

Further, when the substrate delivery device comprises a storage catridge, the delivery method further comprises:

step five: the screen release arm being used for delivering the substrate thereon into a storage cabinet of the storage catridge;

step six: controlling the storage catridge to move along the third direction Z so as to receive a next substrate, repeating the step five and the step six until the storage catridge is filled fully with substrates. The mechanical hand in the next manufacturing process picks up the storage catridge that is filled fully with substrates 1.

Apparently, the skilled person in the art can make various modifications and variations to the embodiments of the present invention without departing from the spirit and the scope of the present invention. These modifications and variations to the embodiments of the present invention belong to the scopes of the claims of the present invention and the equivalent technologies thereof.

1. A substrate delivery device comprising: a reciprocating aligning mechanism and a screen pickup mechanism; wherein
the reciprocating aligning mechanism comprises a bearing platform for carrying the substrate, and a first driving mechanism for driving the bearing platform to move so as to bring the carried substrate to a preset position;
wherein the screen pickup mechanism comprises a pickup arm for picking up a substrate on the reciprocating aligning mechanism, and a second driving mechanism for driving the pickup arm to move;
wherein the pickup arm is located in a direction perpendicular to the substrate on the reciprocating aligning mechanism; and
wherein when the reciprocating aligning mechanism moves to the preset position, the second driving mechanism is used for driving the pickup arm to pick up the substrate on the reciprocating aligning mechanism.

2. The substrate delivery device according to claim 1, further comprising at least one screen release arm onto which the screen pickup mechanism transfers the picked-up substrate; wherein each of the at least one screen release arm comprises a delivery platform for carrying the substrate transferred by the screen pickup mechanism, and a third driving mechanism for driving the delivery platform to move.

3. The substrate delivery device according to claim 2, wherein the number of the at least one screen release arm is two, and the two screen release arms are in axial symmetry relative to a moving direction of any screen release arm.

4. The substrate delivery device according to claim 3, wherein the first driving mechanism comprises:
a first driving unit for driving the bearing platform to move along a first direction;
a second driving unit for driving the bearing platform to move along a second direction, wherein the second direction is parallel to arrangement direction of the two screen release arms, and the first direction is perpendicular to the second direction.

5. The substrate delivery device according to claim 4, wherein the first driving unit comprises a first lead screw and a first driving motor for driving the first lead screw to rotate, the bearing platform being in sliding connection with the first lead screw; and,
wherein the second driving unit comprises a second lead screw and a second driving motor for driving the second lead screw to rotate, the bearing platform being in sliding connection with the second lead screw.

6. The substrate delivery device according to claim 4, further comprising a guide rail located above the reciprocating aligning mechanism, wherein an extending direction of the guide rail is parallel to the second direction; and the screen pickup mechanism can be connected with the reciprocating aligning mechanism through the guide rail.

7. The substrate delivery device according to claim 4, wherein the second driving mechanism comprises
a third driving unit for driving the pickup arm to move along a third direction;
a fourth driving unit for driving the pickup arm to move along the second direction, the third direction being perpendicular to both the first direction and the second direction.

8. The substrate delivery device according to claim 7, wherein the third driving unit is arranged within a mounting rack, and the third driving unit comprises a third lead screw and a third driving motor for driving the third lead screw to rotate, the pickup arm being in sliding connection with the third lead screw; and,
wherein the fourth driving unit comprises a fourth lead screw and a fourth driving motor for driving the fourth lead screw to rotate, the mounting rack being in sliding connection with the fourth lead screw.

9. The substrate delivery device according to claim 2, wherein the third driving mechanism comprises a fifth lead screw and a fifth driving motor for driving the fifth lead screw to rotate, the delivery platform being in sliding connection with the fifth lead screw.

10. The substrate delivery device according to claim 2, wherein the delivery platform is provided with a plurality of vacuum suction holes for adsorbing the substrate transferred by the screen pickup mechanism.

11. The substrate delivery device according to claim 1, wherein the pickup arm is provided with a vacuum chuck for adsorbing the substrate.

12. The substrate delivery device according to claim 4, further comprising:
a storage catridge arranged at one end of each of the at least one screen release arm away from the reciprocating aligning mechanism, for storing the substrate delivered by each screen release arm, wherein the storage catridge comprises at least two layers of storage cabinet, each layer of storage cabinet being used for accommodating one substrate;
a fourth driving mechanism corresponding to the storage catridge, for driving the corresponding storage catridge to move along a third direction; wherein the third direction is perpendicular to both the first direction and the second direction.

13. A delivery method applied to the substrate delivery device comprising the steps of:
step one: placing a substrate to be delivered on a bearing platform of a reciprocating aligning mechanism;
step two: providing a first driving mechanism in the reciprocating aligning mechanism to drive the bearing platform to move so as to bring the carried substrate to a preset position;
step three: providing a second driving mechanism in a screen pickup mechanism to drive the pickup arm in the screen pickup mechanism to pick up the substrate on the reciprocating aligning mechanism;
wherein the substrate delivery device comprises the reciprocating aligning mechanism and the screen pickup mechanism;
wherein the reciprocating aligning mechanism comprises the bearing platform for carrying the substrate, and the first driving mechanism for driving the bearing platform to move so as to bring the carried substrate to a preset position;
wherein the screen pickup mechanism comprises a pickup arm for picking up a substrate on the reciprocating aligning mechanism, and the second driving mechanism for driving the pickup arm to move;
wherein the pickup arm is located in a direction perpendicular to the substrate on the reciprocating aligning mechanism; and
wherein when the reciprocating aligning mechanism moves to the preset position, the second driving mechanism is used for driving the pickup arm to pick up the substrate on the reciprocating aligning mechanism.

14. The delivery method according to claim 13, wherein the substrate delivery device comprises at least one screen release arm onto which the screen pickup mechanism transfers the picked-up substrate, the delivery method further comprises:
step four: providing the first driving mechanism in the reciprocating aligning mechanism to drive the bearing platform to move to an initial position, and repeating the step one, the step two and the step three; meanwhile, and
repeating the step four after the second driving mechanism in the screen pickup mechanism drives the pickup arm in the screen pickup mechanism to transfer the picked-up substrate to a screen release arm.

15. The delivery method according to claim 14, wherein the substrate delivery device comprises a storage catridge arranged at one end of each of the at least one screen release arm away from the reciprocating aligning mechanism, for storing the substrate delivered by each screen release arm, wherein the storage catridge comprises at least two layers of storage cabinet, each layer of storage cabinet being used for accommodating one substrate, the delivery method further comprises:
step five: using the screen release arm to deliver the substrate thereon into a storage cabinet of the storage catridge;
step six: controlling the storage catridge to move next storage cabinet so as to receive a next substrate, and
repeating the step five and the step six until the storage catridge is filled fully with substrates.
